(19) United States
(12) Patent Application Publication
(10) Pub. No.: US 2011/0215855 A1
(43) Pub. Date: Sep. 8, 2011

(54) VOLTAGE GENERATING CIRCUIT

(75) Inventor: Naoki OOKUMA, Kanagawa (JP)

(73) Assignee: RENESAS ELECTRONICS CORPORATION, Kanagawa (JP)

(21) Appl. No.: 13/040,752

(22) Filed: Mar. 4, 2011

(30) Foreign Application Priority Data
Mar. 4, 2010 (JP) 2010-047539

(51) Int. Cl. H03K 3/00

(52) U.S. Cl. 327/295

(57) ABSTRACT

A voltage generating circuit has: an operational amplifier, first to third voltage generating units, a first resistor and a second resistor. The operational amplifier generates a control signal depending on first and second voltages that are input thereto. The first voltage generating unit generates the first voltage depending on the control signal and outputs the first voltage from a first node. The second voltage generating unit generates the second voltage depending on the control signal and outputs the second voltage from a second node. The third voltage generating unit generates a third voltage as a reference voltage depending on the control signal and outputs the third voltage from a reference voltage output node. The first resistor is connected between the first node and the reference voltage output node. The second resistor connected between the second node and the reference voltage output node.

### INCORPORATION BY REFERENCE

This application is based upon and claims the benefit of priority from Japanese patent application No. 2010-047539, filed on Mar. 4, 2010, the disclosure of which is incorporated herein in its entirety by reference.

### BACKGROUND OF THE INVENTION

1. Field of the Invention

The present invention relates to a voltage generating circuit. In particular, the present invention relates to a voltage generating circuit that generates a predetermined voltage used as a bandgap reference voltage of a semiconductor device.

2. Description of Related Art

In recent years, global warming countermeasures have been promoted on a global scale. Regarding an LSI (Large Scale Integrated circuit) also, demand for low power consumption is increasing. In a case of a logic circuit, low power consumption is achieved by reducing a power supply voltage. However, in a case of an analog circuit such as a bandgap reference voltage generating circuit, its circuit operation becomes difficult due to the reduction in the power supply voltage. Therefore, demand for a low power consumption analog circuit capable of operating at a low power supply voltage is increasing.

FIG. 1 is a circuit diagram showing a configuration of a low-voltage bandgap reference voltage generating circuit that is disclosed in Patent Literature 1 (Japanese Patent Publication JP-2007-95031). It should be noted that reference numerals used in FIG. 1 do not match those described in the Patent Literature 1.

In the low-voltage bandgap reference voltage generating circuit shown in FIG. 1, each of nodes N_{A} and N_{B} is connected to a node N_{C} through a resistor R_{C}, and the node N_{C} is connected to a ground through a resistor R_{B}. Thus, a common current division path can be used, and a low power supply voltage operation is achieved. A reference voltage V_{REF} is expressed as the following Formula 1.

V_{REF}=(R_{D}/(R_{C}+2R_{B}))(((R_{C}+2R_{B})×V_{T}×ln(m)/R_{A})+V_{F}) [Formula 1]

Here, V_{T} is a thermal voltage, an area ratio between diodes D_{A} and D_{B} is D_{A}:D_{B}=1:m, and V_{F} is a forward voltage (=V_{A}) of the diode.

Next, a consumption current will be considered below. It should be noted that a current consumed by an operational amplifier is not included. Since a non-inverting input voltage V_{A} and an inverting input voltage V_{B} are so controlled by the operational amplifier as to be equal to each other, a current I_{A} is expressed as the following Formula 2.

I_{A}=V_{T}×ln(m)/R_{A} [Formula 2]

A current I_{B} is expressed as the following Formula 3.

I_{B}=V_{A}(R_{C}/2)+R_{B})=2V_{F}/(R_{C}+2R_{B}) [Formula 3]

Transistors MP_{A}, MP_{B} and MP_{C} have the same size. Therefore, the consumption current is three times a current I_{D} and can be expressed as the following Formula 4.

3I_{D}=3(I_{A}+(I_{B}/2))=(3V_{T}×ln(m)/R_{A})+(3V_{F}/(R_{C}+2R_{B}) [Formula 4]

### SUMMARY

The inventor of the present application has recognized the following points. The bandgap reference voltage generating circuit that operates at a low power supply voltage is provided with the current division path and thus the consumption current becomes larger. In a case of a typical bandgap reference voltage generating circuit that does not operate at a low power supply voltage (and typically outputs a reference voltage V_{REF} about 1.2 V), the term “I_{B}/2” is not included in the Formula 4. That is, the term “I_{B}/2” is added for achieving the low power supply voltage operation. Therefore, in the case of the low-voltage bandgap reference voltage generating circuit shown in FIG. 1, reduction in the consumption current is not sufficient.

In an aspect of the present invention, a voltage generating circuit is provided. The voltage generating circuit has an operational amplifier, a first voltage generating unit, a second voltage generating unit, a third voltage generating unit, a first resistor and a second resistor. The operational amplifier is configured to generate a control signal depending on a first voltage and a second voltage that are input thereto. The first voltage generating unit is configured to generate the first voltage depending on the control signal and to output the first voltage from a first voltage output node. The second voltage generating unit is configured to generate the second voltage depending on the control signal and to output the second voltage from a second voltage output node. The third voltage generating unit is configured to generate a third voltage as a reference voltage depending on the control signal and to output the third voltage from a reference voltage output node. The first resistor is connected between the first voltage output node and the reference voltage output node. The second resistor connected between the second voltage output node and the reference voltage output node.

According to the voltage generating circuit of the present invention, not only the low power supply voltage operation is achieved but also the consumption current can be reduced sufficiently.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a circuit diagram showing a configuration of a low-voltage bandgap reference voltage generating circuit described in the Patent Literature 1; and

FIG. 2 is a circuit diagram showing a configuration of a voltage generating circuit according to an embodiment of the present invention.

### DESCRIPTION OF PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposed.

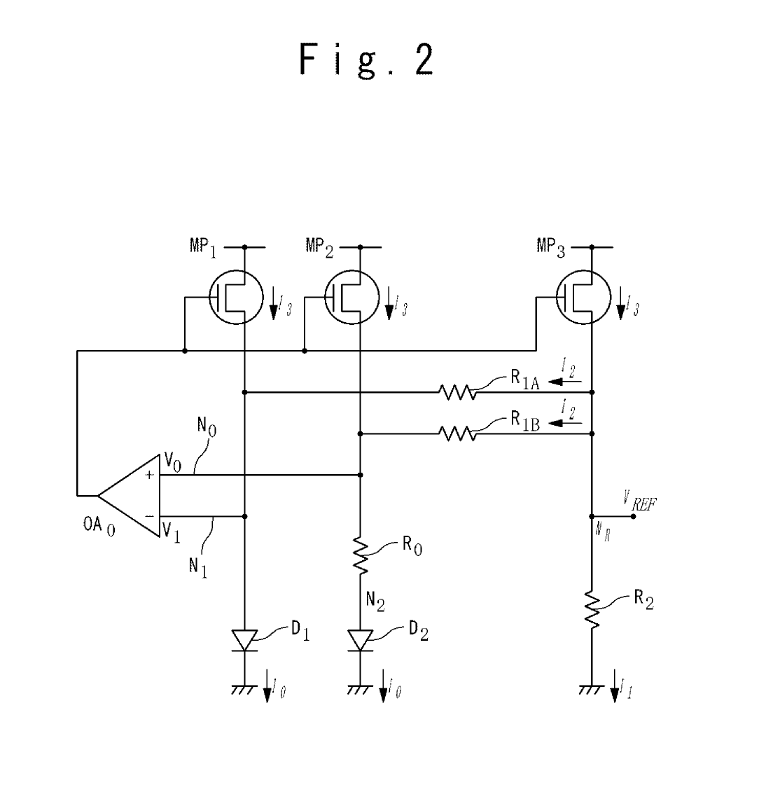

FIG. 2 is a circuit diagram showing a configuration of a voltage generating circuit according to an embodiment of the present invention.

The voltage generating circuit shown in FIG. 2 has first to third PMOS (P-channel Metal Oxide Semiconductor) transistors MP₁, MP₂ and MP₃, resistors R₀, R_{1A}, R_{1B} and R₂, diodes D₁ and D₂, and an operational amplifier OA₀. The first to third PMOS transistors MP₁, MP₂ and MP₃ have the same transistor characteristic. An area ratio between the diodes D₁ and D₂ is D₁:D₂=1:m. It should be noted that each of the diodes D₁ and D₂ can be replaced by a diode-connected bipolar transistor.

The operational amplifier OA₀ has an inverting input terminal connected to a node N₁ and a non-inverting input terminal connected to a node N₀. A first voltage V₁ of the node N₁ and a second voltage V₀ of the node N₀ are input to the operational amplifier OA₀. The operational amplifier OA₀ generates and outputs a control signal depending on the first voltage V₁ and the second voltage V₀. An output terminal of the operational amplifier OA₀ is connected to gates of the first to third PMOS transistors MP₁, MP₂ and MP₃, and the control signal is input to the gates of the first to third PMOS transistors MP₁, MP₂ and MP₃.

A source of the first PMOS transistor MP₁ is connected to a power supply terminal. A drain of the first PMOS transistor MP₁ is connected to the node N₁. The node N₁ is connected to one end of the resistor R_{1A}, the inverting input terminal of the operational amplifier OA₀ and an anode of the first diode D₁. A cathode of the first diode D₁ is connected to a ground. Here, the first PMOS transistor MP₁ and the first diode D₁ as a whole functions as a first voltage generating unit. The first voltage generating unit (MP₁, D₁) generates the first voltage V₁ depending on the control signal and outputs the first voltage V₁ from the node N₁.

A source of the second PMOS transistor MP₂ is connected to the power supply terminal. A drain of the second PMOS transistor MP₂ is connected to the node N₀. The node N₀ is connected to the non-inverting input terminal of the operational amplifier OA₀, one end of the resistor R_{1B}, and one end of the resistor R₀. The other end of the resistor R₀ is connected to a node N₂. The node N₂ is connected to an anode of the second diode D₂. A cathode of the second diode D₂ is connected to the ground. Here, the second PMOS transistor MP₂, the resistor R₀ and the second diode D₂ as a whole functions as a second voltage generating unit. The second voltage generating unit (MP₂, R₀, D₂) generates the second voltage V₀ depending on the control signal and outputs the second voltage V₀ from the node N₀.

A source of the third PMOS transistor MP₃ is connected to the power supply terminal. A drain of the third PMOS transistor MP₃ is connected to a node N_{R} from which a reference voltage V_{REF} is output. The node N_{R} is connected to the other end of the resistor R_{1A}, the other end of the resistor R_{1B} and one end of the resistor R₂. The other end of the resistor R₂ is connected to the ground. Here, the third PMOS transistor MP₃ and the resistor R₂ as a whole functions as a third voltage generating unit. The third voltage generating unit (MP₃, R₂) generates the reference voltage V_{REF} depending on the control signal and outputs the reference voltage V_{REF} from the node N_{R}.

The resistor R_{1A} is connected between the node N₁ and the node N_{R}. The resistor R_{1B} is connected between the node N₀ and the node N_{R}. Preferably, the resistors R_{1A} and R_{1B} have the same resistance value.

A first path is from the power supply terminal to the ground through the first PMOS transistor MP₁ and the diode D₁. A second path is from the power supply terminal to the ground through the second PMOS transistor MP₂, the resistor R₀ and the diode D₂. A third path is from the power supply terminal to the ground through the third PMOS transistor MP₃ and the resistor R₂. The resistor R_{1A} is connected between the node N₁ on the first path and the node N_{R} on the third path. The resistor R_{1B} is connected between the node N₀ on the second path and the node N_{R} on the third path. The operational amplifier OA₀ ON/OFF controls the respective PMOS transistors MP₁, MP₂ and MP₃ so as to feed-back control the first voltage V₁ of the node N₁ and the second voltage V₀ of the node N₀ to be the same voltage.

Next, let us consider the reference voltage V_{REF} according to the present embodiment. It should be noted here that, in the present embodiment, the resistor R_{1A} and the resistor R_{1B} have substantially the same resistance value, and the resistance value of the resistor R_{1A}, and the resistor R_{1B} each is expressed as “R₁”.

Since the node N₀ and the node N₁ are controlled to be the same voltage, the first voltage V₁ (inverting input voltage) and the second voltage V₀ (non-inverting input voltage) become the same voltage V_{F}. Here, the voltage V_{F} is a forward voltage of the diode D₁. A current path related to the second PMOS transistor MP₂ and the resistor R_{1B} connected to the node N₀ is substantially the same as a current path related the first PMOS transistor MP₁ and the resistor R_{1A} connected to the node N₁. Therefore, a current flowing through the diode D₁ is substantially equal to a current flowing through the diode D₂. The current I₀ flowing through the diodes D₁ and D₂ each is expressed as the following Formula 5. Here, V_{T} is a thermal voltage

I₀=V_{T}×ln(m)/R₀ [Formula 5]

Whereas, a current I₂ flowing through the resistor R_{1A} (R_{1B}) is defined as a current flowing in a direction from the node N_{R} toward the node N₁ (node N₀). The current I₂ is expressed as the following Formula 6.

I₂=(V_{REF}−V_{F})/R₁ [Formula 6]

Regarding a current I₃ and a current I₁ shown in FIG. 2, the following Formula 7 and Formula 8 can be obtained.

I₃=I₀−I₂=(V_{T}×ln(m)/R₀)−((V_{REF}−V_{F})/R₁) [Formula 7]

I₁=V_{REF}/R₂ [Formula 8]

When the Kirchhoff's current law is applied to the node N_{R}, the following Formula 9 can be obtained.

I₃=I₁+2I₂ [Formula 9]

Therefore, by substituting the Formulas 6 to 8 into the Formula 9, we obtain the following Formula 10.

V_{REF}=(3R₂/(R₁+3R₂))((R₁V_{T}×ln(m)/3R₀)+V_{F}) [Formula 10]

Next, let us consider the consumption current according to the present embodiment. It should be noted that a current consumed by the operational amplifier OA₀ is not included. Since the current I₃ flowing through the first to third PMOS transistors MP₁, MP₂ and MP₃ each is the same, the total consumption current is equal to three times the current I₃. By using the foregoing Formulas 6, 8, 9 and 10, the total consumption current is expressed as the following Formula 11.

3I₃=3(I₁+2I₂)=3((V_{REF}/R₂)+2(V_{REF}−V_{F})/R₁)=((3/R₀)((R₁+2R₂)/(R₁+3R₂))V_{T}×ln(m))+(3V_{F}/(R₁+3R₂)) [Formula 11]

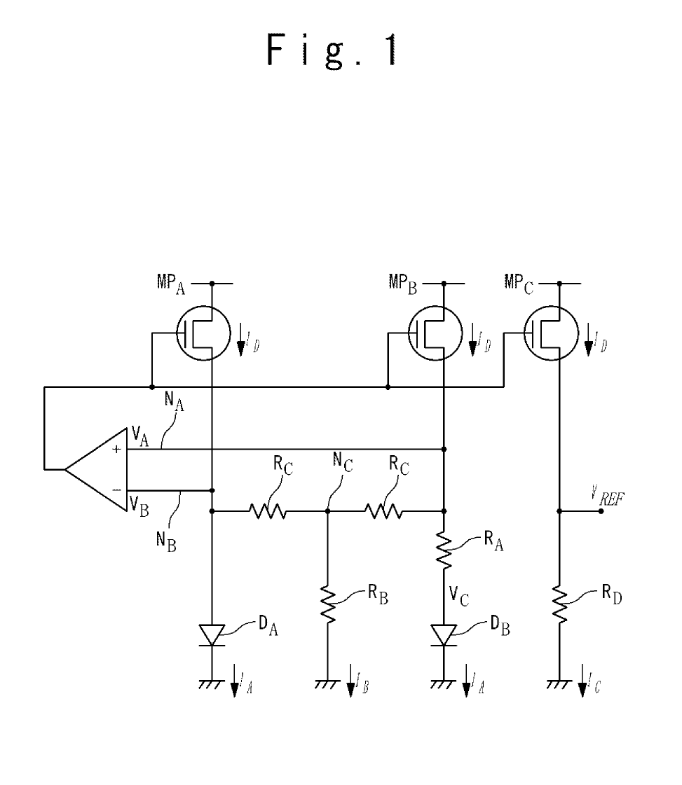

Next, let us compare the consumption current between the present embodiment and the related technique shown in FIG. 1. For comparison, the reference voltage is set to the same value, and a temperature coefficient is set to the same value. Let us consider a case where the coefficients in the foregoing Formula 1 are set as expressed by the following Formulas 12a to 12c.

R_{A}=R [Formula 12a]

R_{D}/(R_{C}+2R_{B})=1/2 [Formula 12b]

(R_{C}+2R_{B})/R_{A}=10 [Formula 12c]

Based on the Formulas 12a to 12c, the following Formulas 13a to 13c can be obtained.

R_{B}=3R [Formula 13a]

R_{C}=4R [Formula 13b]

R_{D}=5R [Formula 13c]

By substituting the Formulas 13a to 13c into the foregoing Formula 4, we obtain the following Formula 14 as a total consumption current Iₜₒₜₐₗ in the case of the related technique shown in FIG. 1.

Iₜₒₜₐₗ=(3V_{T}×ln(m)/R)+(3V_{F}/10R) [Formula 14]

The same coefficient condition as in the case of the related technique is applied to the present embodiment. That is, let us consider a case where the coefficients in the foregoing Formula 10 are set as expressed by the following Formulas 15a to 15c.

R₀=R [Formula 15a]

3R₂/(R₁+3R₂)=1/2 [Formula 15b]

R₁/3R₀=10 [Formula 15c]

Based on the Formulas 15a to 15c, the following Formulas 16a and 16b can be obtained.

R₁=30R [Formula 16a]

R₂=10R [Formula 16b]

By substituting the Formulas 16a and 16b into the Formula 11, we obtain the following Formula 17 as a total consumption current Iₜₒₜₐₗ′ in the case of the present embodiment.

Iₜₒₜₐₗ′=(5V_{T}×ln(m)/2R)+(V_{F}/20R) [Formula 17]

Here, let us compare the consumption current Iₜₒₜₐₗ in the related technique (Formula 14) and the consumption current Iₜₒₜₐₗ′ in the present embodiment (Formula 17). Specifically, the coefficient of the term “V_{T}×ln(m)” and the coefficient of the term “V_{F}” are compared between Formula 14 and Formula 17, resulting in the following Formulas 18a and 18b.

3/R>5/2R [Formula 18a]

3/10R>1/20R [Formula 18b]

Therefore, it can be understood that the consumption current Iₜₒₜₐₗ′ in the present embodiment is smaller than the consumption current Iₜₒₜₐₗ in the related technique. For example, in a case of R=10 KΩ, V_{T}=26 mV, V_{F}=0.7 V and m=8, the following Formulas 19a and 19b is obtained.

Iₜₒₜₐₗ=about 37 μA [Formula 19a]

Iₜₒₜₐₗ′=about 17 μA [Formula 19b]

In a low power supply voltage application, a bandgap reference voltage generating circuit may not operate and thus a booster circuit may be necessary for operating it. However, power loss is caused in the booster circuit. Therefore, the bandgap reference voltage generating circuit with the low consumption current according to the present embodiment is particularly useful.

According to the present embodiment as described above, the following effects can be obtained.

1. The consumption current can be reduced.

2. The power consumption is further reduced when implemented combined with a booster circuit.

It is apparent that the present invention is not limited to the above embodiments and may be modified and changed without departing from the scope and spirit of the invention.

What is claimed is:

1. A voltage generating circuit comprising:
an operational amplifier configured to generate a control signal depending on a first voltage and a second voltage that are input thereto;
a first voltage generating unit configured to generate said first voltage depending on said control signal and to output said first voltage from a first voltage output node;
a second voltage generating unit configured to generate said second voltage depending on said control signal and to output said second voltage from a second voltage output node;
a third voltage generating unit configured to generate a third voltage as a reference voltage depending on said control signal and to output said third voltage from a reference voltage output node;
a first resistor connected between said first voltage output node and said reference voltage output node; and
a second resistor connected between said second voltage output node and said reference voltage output node.

2. The voltage generating circuit according to claim 1,
wherein said first voltage generating unit comprises:
a first PMOS transistor whose source and drain are connected to a power supply terminal and said first voltage output node, respectively, and to whose gate said control signal is input; and
a first diode connected between said first voltage output node and a ground.

3. The voltage generating circuit according to claim 2,
wherein said second voltage generating unit comprises:
a second PMOS transistor whose source and drain are connected to said power supply terminal and said second voltage output node, respectively, and to whose gate said control signal is input;
a third resistor whose one end is connected to said second voltage output node; and
a second diode connected between another end of said third resistor and said ground.

4. The voltage generating circuit according to claim 3,
wherein said third voltage generating unit comprises:
a third PMOS transistor whose source and drain are connected to said power supply terminal and said reference voltage output node, respectively, and to whose gate said control signal is input; and
a fourth resistor connected between said reference voltage output node and said ground.

5. The voltage generating circuit according to claim 4,
wherein said first PMOS transistor, said second PMOS transistor and said third PMOS transistor have a same characteristic.

6. The voltage generating circuit according to claim 1,
wherein said first resistor and said second resistor have a same resistance value.
